(19) United States
(12) Patent Application Publication
(10) Pub. No.: US 2018/0090708 A1
(43) Pub. Date: Mar. 29, 2018

(54) DISPLAY DEVICE

(71) Applicant: Japan Display Inc., Tokyo (JP)

(72) Inventor: Hiraaki KOKAME, Tokyo (JP)

(21) Appl. No.: 15/681,873

(22) Filed: Aug. 21, 2017

(30) Foreign Application Priority Data
Sep. 26, 2016 (JP) 2016-186724

(51) Int. Cl. H01L 51/52; H01L 51/50; H01L 27/12

(52) U.S. Cl. CPC H01L 51/524; H01L 51/0002; H01L 27/1203; H01L 51/5012

(57) ABSTRACT

A display device includes a substrate including a display region, a plurality of pixels arranged in the display region, and a sealing layer covering at least the entire display region. The sealing layer includes a first inorganic insulating layer, a first organic insulating layer arranged above the first inorganic insulating layer, a second organic insulating layer arranged above the first organic insulating layer and having a higher moisture permeability than the first organic insulating layer, and a second inorganic insulating layer arranged above the second organic insulating layer.

### CROSS REFERENCE TO RELATED APPLICATIONS

This application is based upon and claims the benefit of priority from the prior Japanese Patent Application No. 2016-186724, filed on Sep. 26, 2016, the entire contents of which are incorporated herein by reference.

### FIELD

An embodiment of the present invention is related to a sealing structure of a display device.

### BACKGROUND

In an organic electroluminescence (hereinafter referred to as organic EL) display device, light emitting elements are arranged in each pixel, and images are displayed by individually controlling light emission. A light emitting element has a structure in which a layer including an organic EL material (hereinafter also referred to as “light emitting layer”) is sandwiched between a pair of electrodes which are distinguished as an anode and the other as a cathode. When electrons are injected into the light emitting layer from the cathode and holes are injected from the anode, electrons and holes recombine. As a result, light emitting molecules in the light emitting layer are excited by the surplus energy emitted and then de-excited to emit light.

In an organic EL display device, the anode of each light emitting element is arranged as a pixel electrode for each pixel, and the cathode is arranged as a common electrode which is applied with a common potential across a plurality of pixels. The organic EL display device controls the light emission of a pixel by applying the potential of the pixel electrode to each pixel with respect to the potential of the common electrode.

However, there is a problem whereby the light emitting layer of the organic EL display device easily deteriorates when moisture enters, and a non-lighting region called a dark spot occurs. In order to solve such a problem, many organic EL display devices are arranged provided with a sealing layer for preventing the infiltration of moisture.

For example, Japanese Laid Open Patent Publication No. 2015-228314 discloses an electronic device arranged with a substrate, an electronic element, a first barrier layer, an organic layer and a second barrier layer sequentially stacked on the substrate, wherein the organic layer is stacked in contact with the first barrier layer, and the second barrier layer which has a higher water vapor permeability than the first barrier layer is stacked in contact with the organic layer and has a higher water vapor permeability than the organic layer.

### SUMMARY

A display device related to one embodiment of the present invention includes a substrate including a display region, a plurality of pixels arranged in the display region, and a sealing layer covering the display region. The sealing layer includes a first inorganic insulating layer, a first organic insulating layer arranged above the first inorganic insulating layer, a second organic insulating layer arranged above the first organic insulating layer and having a higher water vapor permeability than the first organic insulating layer, and a second inorganic insulating layer arranged above the second organic insulating layer.

### BRIEF DESCRIPTION OF DRAWINGS

FIG. 1 is a perspective view diagram for explaining an outline structure of a display device related to one embodiment of the present invention;

FIG. 2 is a cross-sectional diagram for explaining the structure of a display device related to one embodiment of the present invention;

FIG. 3A is a diagram for explaining the infiltration of water in the case where a sealing layer is used which does not have a second organic insulating layer with respect to a sealing layer related to one embodiment of the present invention;

FIG. 3B is a diagram for explaining the infiltration of water in the case where a sealing layer is used related to one embodiment of the present invention;

FIG. 4 is a cross-sectional diagram for explaining the structure of a display device related to one embodiment of the present invention; and

FIG. 5 is a cross-sectional diagram for explaining the structure of a display device related to one embodiment of the present invention.

### DESCRIPTION OF EMBODIMENTS

A display device related to a number of embodiments of the present invention is explained in detail below while referring to the diagrams. Furthermore, the display device of the present invention should not be limited to the embodiments herein and can be modified in various forms. In all of the embodiments, the same reference symbols are attached to similar elements and explained. In addition, the dimension ratios in the drawings may be different compared to their rations in order to better clarify explanation, and therefore parts of the structure may be omitted where appropriate.

### First Embodiment

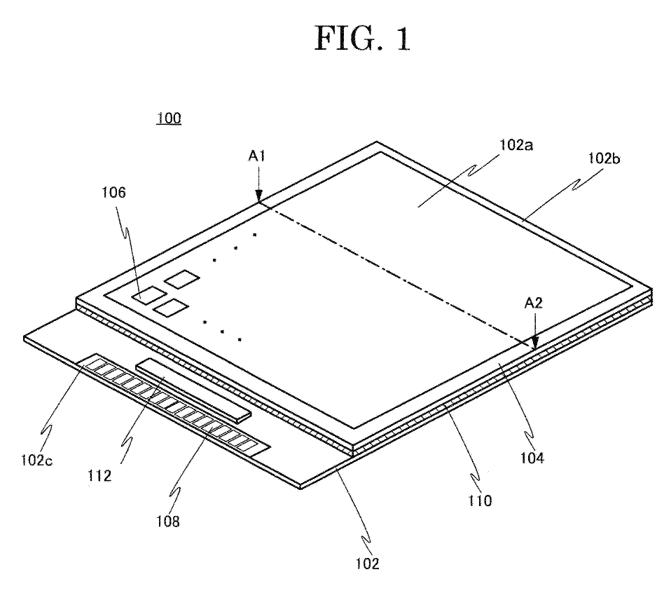

FIG. 1 is a perspective view diagram for explaining an outline structure of a display device 100 related to the present embodiment. The display device 100 related to the present embodiment includes a first substrate 102, a plurality of pixels 106, a second substrate 104, a plurality of connection terminals 108 and a driver IC 112.

The first substrate 102 serves as a support for the plurality of pixels 106 and the plurality of connection terminals 108. In the first substrate 102, a region in which the plurality of pixels 106 is arranged is a display region 102a, a region between an outer periphery part of the display region 102a and an end edge part of the first substrate 102 is a periphery region 102b, and a region where the plurality of connection terminals 108 is arranged is a terminal region 102c. It is possible to use a glass substrate, an acrylic resin substrate and an alumina substrate or the like as the first substrate 102. In addition, the first substrate 102 may also be a substrate having flexibility. A resin material is used as a substrate having flexibility. It is preferred to use a polymer material including an imide bond as a repeating unit as the resin material, for example, polyimide. Specifically, a film substrate obtained by molding polyimide into a sheet shape is used as the substrate.

The second substrate 104 is arranged on an upper surface of the display region 102a of the first substrate 102 so as to face the first substrate 102. The second substrate 104 may be fixed to the first substrate 102 using a sealing material 110 which surrounds a periphery part of the second substrate 104. Furthermore, the sealing material 110 may be appropriately arranged or a resin may be filled onto substantially the entire surface between the first substrate 102 and the second substrate 104.

The same substrate as the first substrate 102 may be used as the second substrate 104. Furthermore, although the display device 100 related to the present embodiment includes the second substrate 104 as mentioned previously, the material is not limited to a board shaped component but may be replaced with a film base material or a sealing base material coated with a resin and the like.

A color filter, a light shielding layer, a polarizing plate and a phase plate and the like may be arranged on the second substrate 104. The color filter is arranged at a position facing each of the plurality of pixels 106. The light shielding layer (also called a black matrix) is arranged at a position that partitions each of the plurality of pixels 106. The polarizing plate and the phase plate cover the plurality of pixels 106 and are arranged on the outer side surface of the second substrate 104. The polarizing plate and the phase plate are arranged in order to suppress degradation in visibility due to external light incident on the display device 100 being reflected by a pixel electrode.

The plurality of pixels 106 are arranged in a matrix shape in the display area 102a on the first substrate 102. Each of the plurality of pixels 106 includes a pixel circuit. Although not shown in the diagram, a pixel circuit includes at least a drive transistor, a selection transistor, a light emitting element and a storage capacitor.

The plurality of connection terminals 108 are arranged in the terminal region 102c of the first substrate 102. The terminal region 102c is arranged at one end of the first substrate 102 and on the outer side of the second substrate 104. In the first substrate 102, a region where a plurality of connection terminals 108 is arranged is the terminal region 102c. A wiring substrate (not shown in the diagram) for connecting the display device 100 with a device which outputs image signals or a power supply and the like is connected to the plurality of connection terminals 108. Contact points with the plurality of connection terminals 108 connected to the wiring substrate are exposed to the exterior.

The driver IC 112 is arranged on the first substrate 102 and on the outer side of the second substrate 104. The driver IC 112 outputs image signals input from the connection terminal 108 to the plurality of pixels 106 arranged in the display area 102a.

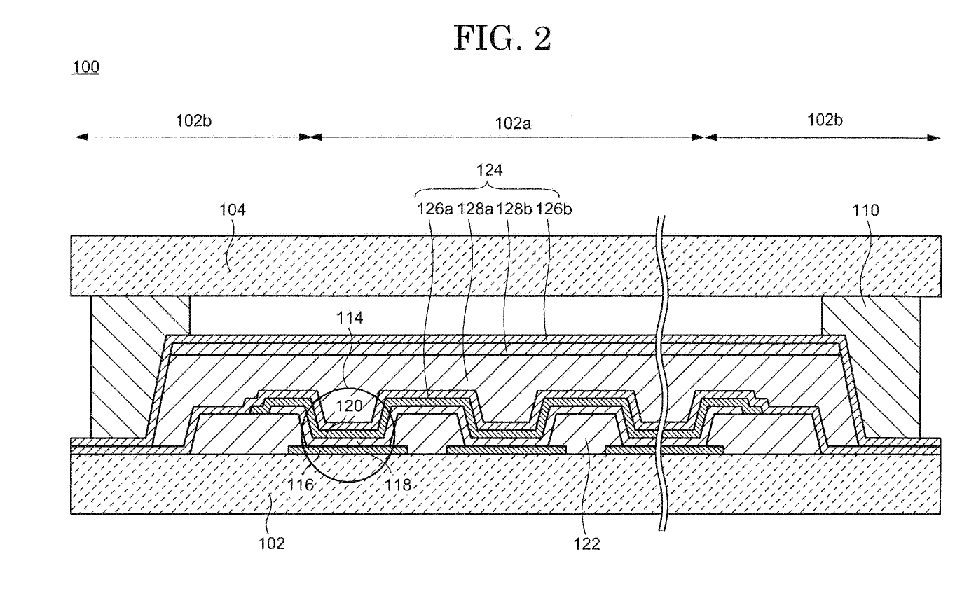

FIG. 2 is a cross-sectional view diagram for explaining the structure of the display device 100 related to the present embodiment. FIG. 2 shows a cross-sectional structure along the line A1-A2 shown in FIG. 1. The display device 100 related to the present embodiment includes the first substrate 102, a plurality of pixels 106, a sealing layer 124, the second substrate 104 and the sealing material 110.

The first substrate 102 serves as a support for the plurality of pixels 106. The plurality of pixels 106 are arranged in the display region 102a over the first substrate 102.

Each of the plurality of pixels 106 is arranged in the display region 102a on the first substrate 102. Each of the plurality of pixels 106 includes at least a selection transistor, a drive transistor, a light emitting element and a pixel circuit having a storage capacitor. Among these, only the light emitting element 114 is shown in FIG. 2.

The light emitting element 114 has a layer structure in which at least a pixel electrode 116, light emitting layer 118 and a common electrode 120 are stacked in this order from the first substrate 102 side. A self-light-emitting type light emitting element 114 can be used as the light emitting element 114. In the present embodiment, it is assumed that an organic EL light emitting element using an organic light emitting layer for the light emitting layer 118 is used as the self-light emitting type light emitting element 114.

The pixel electrode 116 is arranged for each of the plurality of pixels 106. It is preferred that the material of the pixel electrode 116 includes a metal layer with a high reflectance in order to reflect light generated by the light emitting layer 118 to the common electrode 120 side. For example, silver (Ag), an alloy containing silver, aluminum or an alloy containing aluminum or the like can be used as the metal layer with high reflectance.

Furthermore, a transparent conductive layer may also be stacked in addition to the metal layer with high reflectance described previously. ITO (tin oxide added indium oxide), or IZO (indium oxide-zinc oxide) or the like having transparency and conductivity is preferred to be used as the transparent conductive layer. In addition, any combination of these may be used.

The light emitting layer 118 is arranged sandwiched between the pixel electrode 116 and the common electrode 120. An organic EL material which emits light when an electric current is supplied can be used as a material of the light emitting layer 118. A low molecular or high molecular weight organic material can be used as the organic EL material. In the case where a low molecular weight organic material is used, the light emitting layer 118 may include, in addition to the light emitting organic material, a hole injection layer, an electron injection layer, a hole transporting layer and an electron transporting layer and the like. In addition, the light emitting layer 118 may be formed independently for each pixel 106.

The common electrode 120 in the present embodiment is arranged across the plurality of pixels 106. ITO (tin oxide-added indium oxide) or IZO (indium oxide-zinc oxide) having transparency and conductivity are preferably used as the material of the common electrode 120 in order to allow the light generated in the light emitting layer 118 to pass through. Alternatively, a metal layer having a thickness sufficient enough to allow outgoing light to pass through may be used as the common electrode 120. Furthermore, the common electrode 120 may be formed individually for each pixel electrode 116.

A bank 122 is arranged between two adjacent pixel electrodes 116 to define two adjacent pixels 106. The bank 122 is arranged in a layer between the pixel electrode 116 and the light emitting layer 118 and is arranged in order to cover the periphery edge part of the pixel electrode 116.

It is preferred to use an insulating material as the material of the bank 122. An inorganic insulating material or an organic insulating material can be used as the insulating material. For example, silicon oxide, silicon nitride and a combination thereof or the like can be used as the inorganic insulating material. For example, a polyimide resin, an acrylic resin and a combination thereof or the like can be used as the organic insulating material. A combination of an inorganic insulating material and an organic insulating material may also be used.

It is possible to prevent the common electrode 120 and the pixel electrode 116 from short circuiting at the end part of the pixel electrode 116 by arranging the bank 122 formed using an insulating material. Furthermore, it is possible to reliably insulate adjacent pixels 106.

The sealing layer 124 is arranged across the display region 102a and covers the plurality of pixels 106. That is, the sealing layer 124 covers the entire display region 102a. In the present embodiment, the sealing layer 124 includes at least a first inorganic insulating layer 126a, a second inorganic insulating layer 126b, a first organic insulating layer 128a and a second organic insulating layer 128b. These layers which form the sealing layer 124 are stacked from the lower layer in the order of the first inorganic insulating layer 126a, first organic insulating layer 128a, second organic insulating layer 128b and second inorganic insulating layer 126b. These layers are explained in order from the layer on the first substrate 102 side.

The first inorganic insulating layer 126a is arranged in order to block a moisture infiltration path to the light emitting element 114 in the case when the upper layer first organic insulating layer 128a or the second organic insulating layer 128b includes moisture. Therefore, an insulating material having low moisture permeability is preferred as the material of the first inorganic insulating layer 126a. For example, silicon oxide (SiOₓ), silicon nitride (SiNₓ), silicon oxynitride (SiOₓN_{y}), silicon nitride oxide (SiNₓO_{y}), aluminum oxide (AlOₓ), aluminum nitride (AlNₓ), aluminum oxynitride (AlOₓN_{y}) and aluminum nitride oxide (AlNₓO_{y}) and the like can be used as specific examples of the material of the first inorganic insulating layer 126a (x and y are arbitrary). In addition, a structure in which these layers are stacked may also be used. A plasma CVD (Chemical Vapor Deposition) method, a sputtering method or the like can be used as the film formation method of the first inorganic insulating layer 126a.

The first organic insulating layer 128a is arranged above the first inorganic insulating layer 126a. The first organic insulating layer 128a is arranged so as to cover the plurality of pixels 106 in a plan view. In other words, the first organic insulating layer 128a is arranged so as to cover the entire display region 102a in a plan view. In other words, the first organic insulating layer 128a is wider than the light emitting layer 118 in a plan view and is arranged so as to completely cover the light emitting layer 118.

The first organic insulating layer 128a is arranged to flatten any concave and convex parts caused by the plurality of light emitting elements 114 or the bank 122 and the like arranged under the sealing layer 124. If such concave and convex parts are not sufficiently flattened and the second inorganic insulating layer 126b described later is arranged, the second inorganic insulating layer 126b cannot sufficiently cover the concave and convex parts and cracks or pinholes which lead to water infiltration paths are generated in the second inorganic insulating layer 126b in some cases.

The thickness of the first organic insulating layer 128a is preferred to be 10 μm or more and 50 μm or less. If the film thickness of the first organic insulating layer 128a is smaller than this range, the concave and convex parts described above may not be sufficiently flattened. In such a case, coverage of the second inorganic insulating layer 126b arranged in an upper layer is no longer sufficient and a moisture infiltration path such as a crack may occur in the second inorganic insulating layer 126b. On the other hand, if the film thickness of the first organic insulating layer 128a is larger than this range, the translucency of the sealing layer 124 decreases which causes a decrease in the brightness which is observed.

Although described in detail herein, a material having a lower water vapor permeability than the second organic insulating layer 128b arranged thereon is used as the material of the first organic insulating layer 128a. Specifically, a material having a water vapor permeability of 10⁻² g/m²/day or more and 10⁰ g/m²/day or less is used. As such a material, an acrylic resin or an epoxy resin or the like can be used for example. A coating method or an evaporation method or the like can be used as a method for forming the first organic insulating layer 128a.

Furthermore, water vapor permeability is defined as the amount of water vapor passing through a test piece having a unit area in a unit time under the condition of a predetermined temperature and humidity. In the present specification, water vapor permeability is defined as the amount of water vapor passing through a test piece of 1 m² in 24 hours.

The second organic insulating layer 128b is arranged on the first organic insulating layer 128a. The second organic insulating layer 128b is arranged so as to cover the plurality of pixels 106 in a plan view. In other words, the second organic insulating layer 128b is arranged so as to cover the entire display region 102a in a plan view. In other words, the second organic insulating layer 128b is wider than the light emitting layer 118 in a plan view and is arranged so as to cover the light emitting layer 118. In the present embodiment, the second organic insulating layer 128b is arranged in contact with the first organic insulating layer 128a. Here, a region where the first organic insulating layer 128a and the second organic insulating layer 128b are in contact covers the entire display area including at least the plurality of pixels 106 in a plan view.

A material having a higher water vapor permeability than the first organic insulating layer 128a is preferred to be used as the material of the second organic insulating layer 128b. Specifically, it is preferred to use a material having a water vapor permeability of 10² g/m²/day or more and 10³ g/m²/day or less.

If the water vapor permeability of the second organic insulating layer 128b is larger than this range, a large amount of moisture infiltrates via cracks or pinholes or the like in the sealing layer 124 which causes white unevenness across the display region. On the other hand, when the water vapor permeability of the second organic insulating layer 128b is smaller than this range, the density of moisture is not sufficiently uniform by diffusion within the second organic insulating layer 128b, and deterioration of visibility described above is more likely to occur.

For example, a material including any one of polyethylene terephthalate, cycloolefin polymer, polycarbonate and polyimide can be used as such a material. A coating method, an evaporation method or the like can be used as a method for forming the second organic insulating layer 128b.

The second inorganic insulating layer 126b is arranged above the second organic insulating layer 128b. The second inorganic insulating layer 126b includes a region in contact with the first inorganic insulating layer 126a in a plan view. This contacting region surrounds the plurality of pixels 106 in a plan view. That is, the first organic insulating layer 128a and the second organic insulating layer 128b are sealed by the first inorganic insulating layer 126a and the second inorganic insulating layer 126b. By including such a structure, the first organic insulating layer 128a or the second organic insulating layer 128b are not exposed at the periphery edge part of the display device 100. In this way, it is possible to block a moisture infiltration path from the periphery edge part to the interior of the display device 100 via the first organic insulating layer 128a or the second organic insulating layer 128b.

Furthermore, the second inorganic insulating layer 126b includes a region which does not contact the first inorganic insulating layer 126a in the periphery region 102b in a plan view. The second inorganic insulating layer 126b includes a region separated from the first inorganic insulating layer 126a in the peripheral region 102b in a plan view. In other words, in a plan view, the second inorganic insulating layer 126b has a region overlapping the first inorganic insulating layer 126a interposed by at least one of the first organic insulating layer 128a and the second organic insulating layer 128b in the periphery region 102b.

An insulating material having low moisture permeability similar to the first inorganic insulating layer 126a is preferred to be used as the material of the second inorganic insulating layer 126b, and a material similar to that of the first inorganic insulating layer 126a can be used. A plasma CVD method or a sputtering method or the like can be used as a method for forming the second inorganic insulating layer 126b.

Since it is easy for an organic insulating layer to become a moisture infiltration path, when moisture infiltrates to the second organic insulating layer 128b, the moisture reaches the first inorganic insulating layer 126a and may infiltrate to the light emitting layer 118. In the present embodiment, since the first organic insulating layer 128a ensures a high degree of flatness, the second inorganic insulating layer 126b has excellent covering properties so that a moisture infiltration path is unlikely to occur. However, even if moisture infiltrates for some reason, by using a material having higher water vapor permeability for the second organic insulating layer 128b than the first organic insulating layer 128a, the influence of moisture infiltration is locally concentrated without diffusing into the second organic insulating layer 128b and the first organic insulating layer 128a, and thereby it is possible to reduce the influence on display quality.

The actions and effects of the sealing layer 124 having such a structure are explained below using the drawings.

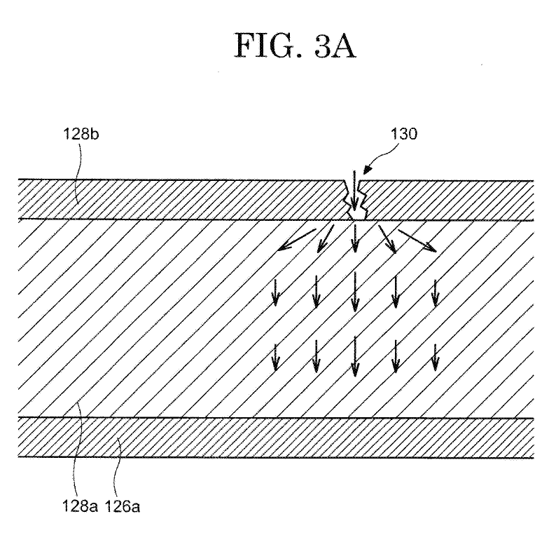

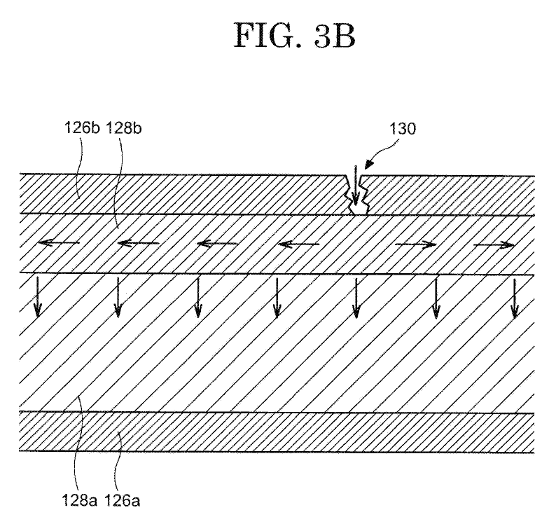

FIG. 3A is a diagram for explaining water infiltration due to cracks 130 produced in the second organic insulating layer 128b in the case where the sealing layer 124 related to the present embodiment does not have a second organic insulating layer 128b. FIG. 3B is a diagram for explaining water infiltration due to cracks 130 produced in a second inorganic insulating layer in the case where the sealing layer 124 related to the present embodiment is used. As is shown in FIG. 3A and FIG. 3B, the case where cracks 130 are produced in the second inorganic insulating layer 126b and water infiltrates to the sealing layer 124 via the cracks 130 is considered.

In the structure shown in FIG. 3A, when moisture infiltrates into the first organic insulating layer 128a from a crack 130 produced in the second inorganic insulating layer 126b, moisture is localized in the vicinity of the crack 130. Here, the density of the localized moisture causes a problem that the optical characteristics of the first organic insulating layer 128a change, transparency decreases, and white unevenness is caused which deteriorates visibility of the display device 100 for example.

On the other hand, with the structure of the sealing layer 124 related to the present embodiment shown in FIG. 3B, when moisture infiltrates into the second organic insulating layer 128b from cracks 130 produced in the second inorganic insulating layer 126b, first, diffusion of moisture in a plane direction of the second organic insulating layer 128b is dominant. This is due to the water vapor permeability of the second organic insulating layer 128b which is higher than the first organic insulating layer 128a. That is, it is difficult for moisture to become localized in the second organic insulating layer 128b and becomes diffused in a plane direction of the second organic insulating layer 128b so that the density becomes uniform.

After the diffusion of moisture in the plane direction of the second organic insulating layer 128b has sufficiently progressed, diffusion of moisture in the thickness direction of the sealing layer 124 becomes dominant. At this time, since the density of moisture is sufficiently uniform in the second organic insulating layer 128b, even if moisture infiltrates into the first organic insulating layer 128a, the density of the water is sufficiently uniform. As a result, it is difficult for the optical characteristics of the first organic insulating layer 128a to change and white unevenness becomes less visible. In this way, it is possible to suppress deterioration in the visibility of the display device 100.

It is possible to delay the time until visibility deteriorates when the density of moisture caused by a change in optical characteristics of the first organic insulating layer 128a is reached as described above. This extends the life of the display device 100 and reliability improves.

Furthermore, the film thickness of the second organic insulating layer 128b is preferably 0.1 μm or more and 5 μm or less. If the film thickness of the second organic insulating layer 128b is smaller than this range, diffusion of moisture in the thickness direction becomes dominant over the plane direction of the sealing layer 124 immediately after moisture infiltrates from the second inorganic insulating layer 126b. In this way, it is easier for moisture to be localized in the first organic insulating layer 128a, and deterioration in visibility is likely to occur. On the other hand, if the film thickness of the second organic insulating layer 128b is larger than this range, translucency of the sealing layer 124 decreases which causes a decrease in the brightness which is observed.

Furthermore, a form in which the first organic insulating layer 128a and the second organic insulating layer 128b are stacked in contact with each other was shown in the present embodiment. The structure of a sealing layer for exhibiting the actions and effects described above is not limited to this structure.

That is, it is sufficient that an organic insulating layer having relatively low water vapor permeability and an inorganic insulating layer in which cracks are relatively easy to occur are not in contact with each other and stacked. When an organic insulating layer having relatively low water vapor permeability and an inorganic insulating layer in which cracks are relatively easy to occur are stacked in contact with each other, moisture infiltrates into the organic insulating layer through cracks in the inorganic insulating layer and may be localized near the cracks. Therefore, an insulating layer may be further interposed between the first organic insulating layer 128a and the second organic insulating layer 128b with respect to the sealing layer related to the present embodiment. However, it is preferable to interpose an organic insulating layer in this case.

As shown in FIG. 2, the second substrate 104 is arranged on the upper surface of the display region 102a of the first substrate 102 so as to face the first substrate 102. The second substrate 104 may be fixed to the first substrate 102 by a sealing material 110.

The sealing material 110 surrounds the periphery part of the second substrate 104 and fixes the first substrate 102 and the second substrate 104. The plurality of pixels 106 arranged on the first substrate 102 are sealed so as not to be exposed to air by the second substrate 104 and the sealing material 110. By such a sealing structure, deterioration of the light emitting element 114 included in each of the plurality of pixels 106 is suppressed.

Furthermore, in the case when the means for fixing the first substrate 102 and the second substrate 104 does not use the sealing material 110, the sealing material 110 is not formed. However, since at least a part of the structural parts used in an alternative means are formed surrounding the periphery part of the second substrate 104, deterioration of the light emitting element 114 included in each of the plurality of pixels 106 can be similarly suppressed.

According to the structure of the display device 100 related to the present embodiment, it is possible to suppress localization of moisture in the sealing layer 124. In this way, it is possible to delay the time until visibility deteriorates when the density of moisture caused by a change in optical characteristics of the first organic insulating layer 128a is reached as described above, the lifetime of the display device 100 is extended and reliability is improved.

### Second Embodiment

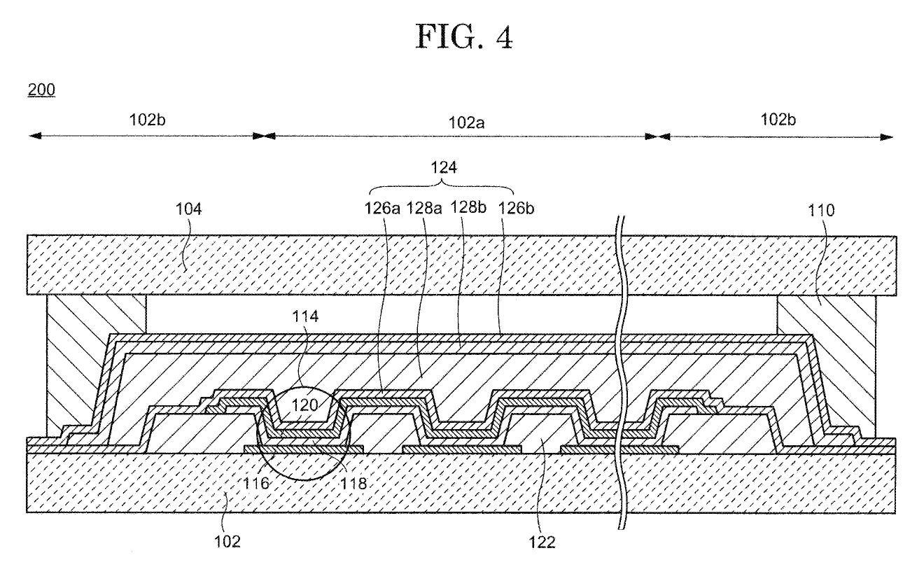

A structure of a display device 200 related to the present embodiment is explained in detail while referring to the drawings. Furthermore, since the schematic structure of the display device 200 related to the present embodiment is the same as that of the display device 100 related to the first embodiment, it is also explained here using FIG. 1. FIG. 4 is a cross-sectional diagram for explaining the structure of the display device 200 related to the present embodiment. FIG. 4 shows a cross-sectional structure along the line A1-A2 shown in FIG. 1.

When the display device 200 related to the present embodiment is compared to the display device 100 related to the first embodiment, the structure of the second organic insulating layer 128b is different. That is, in the present embodiment, the second organic insulating layer 128b covers the end part of the first organic insulating layer 128a. By including such a structure, it is possible to suppress localization of moisture in the vicinity of the end part of the first organic insulating layer 128a when moisture infiltrates from the end part of the sealing layer 124. In this way, it is possible to suppress a change in the optical characteristics of the sealing layer 124 due to localization of moisture, suppress display defects, and extend the life of the display device 200. As in the first embodiment, the sealing material 110 is not necessarily required.

### Third Embodiment

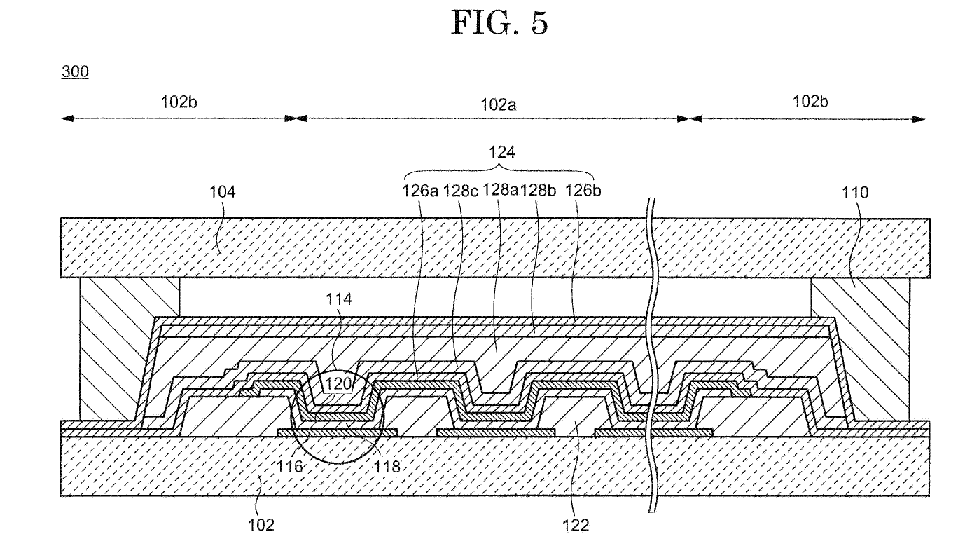

A structure of a display device 300 related to the present embodiment is explained in detail while referring to the drawings. Furthermore, since the schematic structure of the display device 300 related to the present embodiment is the same as that of the display device 100 related to the first embodiment, it is also explained here using FIG. 1. FIG. 5 is a cross-sectional diagram for explaining the structure of the display device 300 related to the present embodiment. FIG. 5 shows a cross-sectional structure corresponding to the line A1-A2 shown in FIG. 1.

When the display device 300 related to the present embodiment is compared with the display device 100 related to the first embodiment, the sealing layer 124 further includes a third organic insulating layer 128c. The third organic insulating layer 128c is arranged between the first inorganic insulating layer 126a and the first organic insulating layer 128a. Furthermore, the third organic insulating layer 128c has higher water vapor permeability than the first organic insulating layer 128a. Furthermore, as in the first embodiment, the sealing material 110 is not necessarily required.

The same material as that of the second organic insulating layer 128b can be used as the material of the third organic insulating layer 128c. The same film thickness of the second organic insulating layer 128b can also be used for third organic insulating layer 128c.

By including such a structure, it is possible to suppress the localization of moisture in the first organic insulating layer 128a from the lower layer of the sealing layer 124, that is, in the case where moisture infiltrates from the pixel 106 side of the sealing layer 124. In this way, it is possible to delay the time until visibility deteriorates when the density of moisture caused by a change in optical characteristics of the first organic insulating layer 128a is reached as described above. In this way, the life of the display device 100 is extended and reliability is improved.

The preferred forms of the present invention were explained above. However, these are merely examples and are not limited to the technical scope of the present invention. A person ordinarily skilled in the art could perform various modifications without departing from the gist of the present invention and therefore, such modifications are naturally to be interpreted as belonging to the technical scope of the present invention.

What is claimed is:

1. A display device comprising:
a substrate including a display region;
a plurality of pixels arranged in the display region; and
a sealing layer covering the display region,
wherein
the sealing layer includes
a first inorganic insulating layer,
a first organic insulating layer arranged above the first inorganic insulating layer,
a second organic insulating layer arranged above the first organic insulating layer and having a higher water vapor permeability than the first organic insulating layer, and
a second inorganic insulating layer arranged above the second organic insulating layer.

2. The display device according to claim 1, wherein the first organic insulating layer and the second organic insulating layer cover the entire display region in a planar view.

3. The display device according to claim 2, wherein the second inorganic insulating layer includes a region contacting the first inorganic insulating layer in a planar view, and the contacting region encloses the entire display region.

4. The display device according to claim 1, wherein the substrate further includes a periphery region between an outer periphery part of the display region and an end edge part of the substrate, and the second inorganic insulating layer includes a region separated from the first inorganic insulating layer in the outer periphery part further to the outer side than the display region in a planar view.

5. The display device according to claim 2, wherein the second organic insulating layer covers an end part of first organic insulating layer.

6. The display device according to claim 2, wherein the sealing layer further includes a third organic insulating layer arranged between the first inorganic insulating layer and the first organic insulating layer, and has a higher moisture permeability than the first organic insulating layer.

7. The display device according to claim 1, wherein a film thickness of the second organic insulating layer is 0.1 μm or more and 5 μm or less.

8. The display device according to claim 1, wherein a film thickness of the first organic insulating layer is 10 μm or more and 50 μm or less.

9. The display device according to claim 1, wherein the second organic insulating layer has a water vapor permeability of 10² g/m²/day or more and 10³ g/m²/day or less.

10. The display device according to claim 1, wherein the first organic insulating layer has a water vapor permeability of 10⁻² g/m²/day or more and 10⁰ g/m²/day or less.

11. The display device according to claim 1, wherein the second organic insulating layer includes any one of polyethylene-telephthalate, cycloolefin polymer, polycarbonate and polyimide.

12. The display device according to claim 1, wherein the second organic insulating layer is arranged in contact with the first organic insulating layer.
